(19) United States
(12) Patent Application Publication
(10) Pub. No.: US 2022/0022337 A1
(43) Pub. Date: Jan. 20, 2022

(54) CIRCUIT BOARD

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventors: Shungo Hiratani, Yokkaichi-shi, Mie (JP); Arinobu Nakamura, Yokkaichi-shi, Mie (JP); Shinsuke Okumi, Yokkaichi-shi, Mie (JP); Akira Haraguchi, Yokkaichi-shi, Mie (JP); Heng Cao, Yokkaichi-shi, Mie (JP)

(21) Appl. No.: 17/260,940

(22) PCT Filed: Jul. 12, 2019
(86) PCT No.: PCT/JP2019/027773

§ 371 Date: Sep. 22, 2021

(30) Foreign Application Priority Data
Jul. 18, 2018 (JP) 2018-135250

(51) Int. Cl. H05K 7/02; H01L 23/14; H01L 25/07; H05K 1/05; H05K 1/18; H05K 7/06

(52) U.S. Cl. CPC H05K 7/026; H01L 23/147; H05K 7/06; H05K 1/05; H05K 1/18; H01L 25/07

(57) ABSTRACT

A power circuit includes multiple bus bars that are connected to multiple terminals of an FET, are provided flush with each other, and are each insulated from each other. The power circuit includes one bus bar that is connected to drain terminals of the FET, a solder fixing portion of the FET that is arranged on the bus bar, and another bus bar that is connected to source terminals of the FET via a conductive connection sheet.

### CROSS-REFERENCE TO RELATED APPLICATIONS

This application is the U.S. national stage of PCT/JP2019/027773 filed on Jul. 12, 2019, which claims priority of Japanese Patent Application No. JP 2018-135250 filed on Jul. 18, 2018, the contents of which are incorporated herein.

### TECHNICAL FIELD

The present disclosure relates to a circuit board.

### BACKGROUND

Conventionally, in a commonly-known circuit board, a conductive pattern for forming a circuit for conducting a relatively small current is formed on a substrate, and conductive pieces (also called bus bars or the like) for forming circuits for conducting a relatively large current are provided on the substrate.

JP 2016-220277A discloses an electrical connection box that includes a pair of bus bars, power semiconductors mounted on the pair of bus bars, a control substrate for mounting a control unit that controls the power semiconductors, and an FPC that is arranged on the upper surfaces of the pair of bus bars and electrically connects control terminals of the power semiconductors to the control substrate.

In a circuit board such as that described above, an insulation portion or a gap is provided between the bus bars in order to insulate the bus bars from each other. Many semiconductor elements include terminals provided on opposite sides of a main body, and in order to connect the terminals of such a semiconductor element to different bus bars, the semiconductor element needs to be arranged in the vicinity of the insulation portion or the gap due to the distance between the terminals and the bus bars, thus limiting the degree of freedom in circuit design.

Further, if the semiconductor element is fixed to the insulation portion, there is also a problem that stress becomes concentrated on the fixing portion of the semiconductor element due to deformation of the insulation portion caused by the difference between the thermal expansion coefficients of the insulation portion and the bus bars on the two sides, thus resulting in damage.

However, even in the electrical connection box of JP 2016-220277A, the power semiconductors (semiconductor elements) are arranged so as to straddle the gap between the bus bars, and the above-described problem cannot be solved.

Therefore, it is an object of the present disclosure to provide a circuit board that can, increase the degree of freedom in arranging a semiconductor element when a plurality of bus bars are used, and also reduces the amount of stress applied to a fixing portion of the semiconductor element.

### Advantageous Effects of the Present Disclosure

According to the present disclosure, it is possible to increase the degree of freedom in arranging a semiconductor element when a plurality of bus bars are used, and also reduce the amount of stress applied to a fixing portion of the semiconductor element.

### SUMMARY

A circuit board according to an aspect of the present disclosure includes a plurality of conductive pieces that are connected to a plurality of terminals of a semiconductor element, are provided flush with each other, and are each insulated from other conductive pieces, the circuit board further including: a first conductive piece connected to a first terminal of the semiconductor element; a fixing portion of the semiconductor element that is arranged on the first conductive piece; and a second conductive piece connected to a second terminal of the semiconductor element via a conductive connection sheet.

### BRIEF DESCRIPTION OF DRAWINGS

FIG. 1 is a front view of an electrical apparatus according to an embodiment.

FIG. 2 is an exploded view of a substrate structure of the electrical apparatus of the embodiment.

FIG. 3 is a plan view of the substrate structure of the electrical apparatus of the embodiment, as seen from above.

FIG. 4 is an enlarged view of a region that includes an FET in FIG. 3.

FIG. 5 is a longitudinal sectional view taken along a line V-V in FIG. 3.

FIG. 6 is an enlarged view of a portion indicated by a dashed-line circle in FIG. 5.

### DETAILED DESCRIPTION OF PREFERRED EMBODIMENTS

First, embodiments of the present disclosure will be listed and described. The embodiments described below may be at least partially combined with each other as desired.

A circuit board according to an aspect of the present disclosure includes a plurality of conductive pieces that are connected to a plurality of terminals of a semiconductor element, are provided flush with each other, and are each insulated from other conductive pieces, the circuit board further including: a first conductive piece connected to a first terminal of the semiconductor element; a fixing portion of the semiconductor element that is arranged on the first conductive piece; and a second conductive piece connected to a second terminal of the semiconductor element via a conductive connection sheet.

In this aspect, the first terminal of the semiconductor element is directly connected to the first conductive piece, the semiconductor element is fixed to the first conductive piece, and the second terminal of the semiconductor element is electrically connected to the second conductive piece via the connection sheet. Accordingly, the semiconductor element does not need to be arranged so as to extend across the insulation portion between the conductive pieces, the degree of freedom in arranging the semiconductor element can be improved, and it is possible to suppress the case where stress is applied to a fixing portion of the semiconductor element due to a difference between the thermal expansion coefficients of the insulation portion and the conductive pieces.

In the circuit board according to another aspect of the present disclosure, the connection sheet is provided on the first conductive piece or the second conductive piece and includes a conductive portion that connects the second terminal and the second conductive piece, and an insulation portion that insulates the first conductive piece from the conductive portion.

In this aspect, the insulation portion insulates at least the first conductive piece and the conductive portion, thus making it possible to prevent a fault from occurring due to an electrical connection between the conductive portion and the first conductive piece.

The circuit board according to another aspect of the present disclosure further includes: a conductive wire that connects a third terminal of the semiconductor element to a member other than the first conductive piece and the second conductive piece; and an insulation sheet that insulates the conductive wire from the first conductive piece and the second conductive piece.

In this aspect, the third terminal of the semiconductor element is connected to a member other than the first conductive piece and the second conductive piece via the conductive wire, and at this time, the insulation sheet insulates the conductive wire from the first conductive piece and the second conductive piece. Accordingly, it is possible to prevent a fault from occurring due to an electrical connection between the conductive wire and the first conductive piece or the second conductive piece.

In the circuit board according to another aspect of the present disclosure, the insulation sheet is adhered to the first conductive piece or the second conductive piece, and the circuit board further includes an upper circuit element arranged on the insulation sheet.

In this aspect, the upper circuit element is arranged on the insulation sheet, and at this time, the insulation sheet insulates the upper circuit element from the first conductive piece or the second conductive piece. Accordingly, another circuit element can be mounted on the first conductive piece or the second conductive piece, and the circuit board can be made more compact.

In the circuit board according to another aspect of the present disclosure, the connection sheet is an FPC (Flexible Printed Circuit).

In this aspect, an FPC is used as the connection sheet. This therefore makes it possible to simplify the process of manufacturing the circuit board.

In the circuit board according to another aspect of the present disclosure, the connection sheet is partially fixed.

In this aspect, the connection sheet is partially (i.e., locally) fixed to the first conductive piece or the second conductive piece. Accordingly, the connection sheet can be loosened, and the connection sheet can undergo thermal expansion or contraction to a certain extent.

In the circuit board according to another aspect of the present disclosure, the first terminal and the second terminal extend in a straight line from a main body of the semiconductor element.

In this aspect, the first terminal and the second terminal extend in a straight line from the main body of the semiconductor element, and the connection sheet is connected to the second terminal. Because the first terminal and the second terminal do not have a bent portion, stress cannot be mitigated by deformation of a bent portion when terminal thermal expansion or contraction occurs, but stress is mitigated by deformation of the connection sheet that is connected to the terminals.

Hereinafter, embodiments of the present disclosure will be described in detail with reference to the drawings. The following describes a circuit board according to an embodiment of the present disclosure with reference to the drawings. Note that the present disclosure is not limited to the following examples, but rather is defined by the claims, and all changes that come within the meaning and range of equivalency of the claims are intended to be embraced therein.

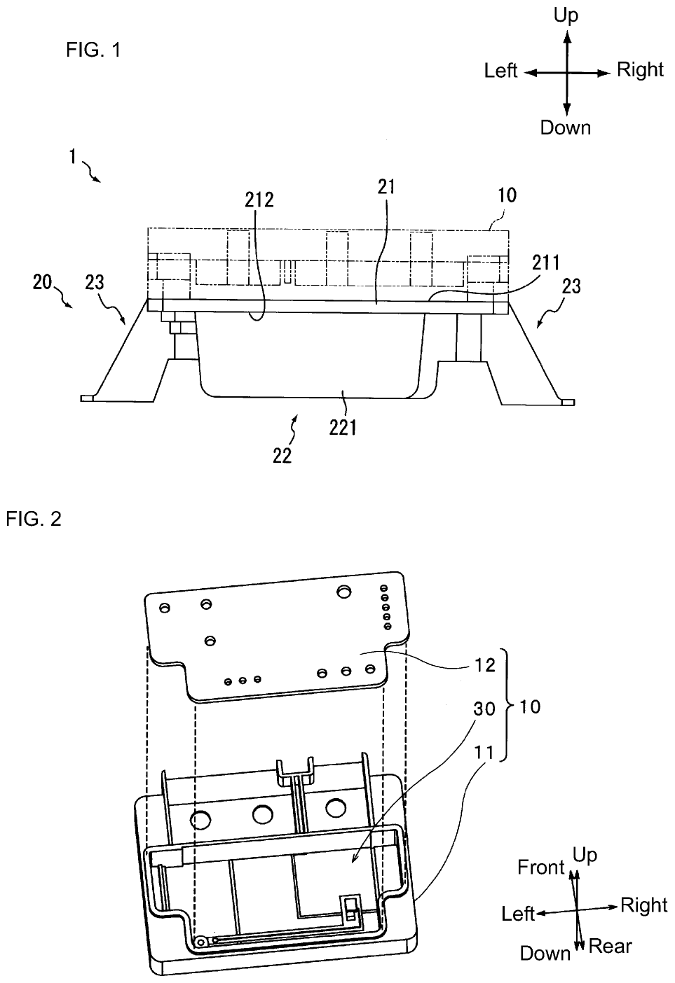

The following description is given by way of example of an electrical apparatus that includes a circuit board according to an embodiment. FIG. 1 is a front view of an electrical apparatus 1 according to the present embodiment.

The electrical apparatus 1 constitutes an electrical connection box for arrangement on a power supply path between a power supply such as a battery included in a vehicle and a load such as a motor or a vehicular electrical component such as a lamp or a wiper. The electrical apparatus 1 is used as a semiconductor element such as a DC-DC converter or an inverter.

The electrical apparatus 1 includes a substrate structure 10 and a support member 20 that supports the substrate structure 10. FIG. 2 is an exploded view of the substrate structure 10 of the electrical apparatus 1 of the present embodiment.

In the present embodiment, for the sake of convenience, “front”, “rear”, “left”, “right”, “up”, and “down” with respect to the electrical apparatus 1 are defined by the front-rear, left-right, and up-down directions shown in FIGS. 1 and 2. The front-rear, left-right, and up-down directions used in the following description are defined as mentioned above.

The substrate structure 10 includes a power circuit 30 (circuit board) and a control circuit 12 that turns the power circuit 30 on and off for example, and the power circuit 30 includes bus bars that form power circuits, and a semiconductor element that is mounted on the bus bars. The semiconductor element is appropriately mounted according to the application of the electrical apparatus 1, and may be a resistor, a coil, a capacitor, or a switching element such as an FET (Field Effect Transistor).

The support member 20 includes a base portion 21 that includes a support surface 211 on the upper side for supporting the substrate structure 10, a heat dissipation portion 22 that is provided on the surface on the side opposite to the support surface 211 (i.e., provided on a lower surface 212), and multiple leg portions 23 that are provided at the left and right ends of the base portion 21 on opposite sides of the heat dissipation portion 22. The base portion 21, the heat dissipation portion 22, and the leg portions 23 of the support member 20 are integrally formed by, for example, performing die casting using a metal material such as aluminum or an aluminum alloy.

The base portion 21 is a flat plate member that is rectangular and has an appropriate thickness. The substrate structure 10 is fixed to the support surface 211 of the base portion 21 using a known method such as adhesion, screwing, or soldering.

The heat dissipation portion 22 includes multiple heat dissipation fins 221 that project downward from the lower surface 212 of the base portion 21 such that heat generated by the substrate structure 10 is dissipated outward. The heat dissipation fins 221 extend in the left-right direction and are arranged parallel with gaps therebetween in the front-back direction.

The leg portions 23 are provided at the left and right ends of the base portion 21. One or more leg portions 23 are provided at each of the left and right ends of the base portion 21.

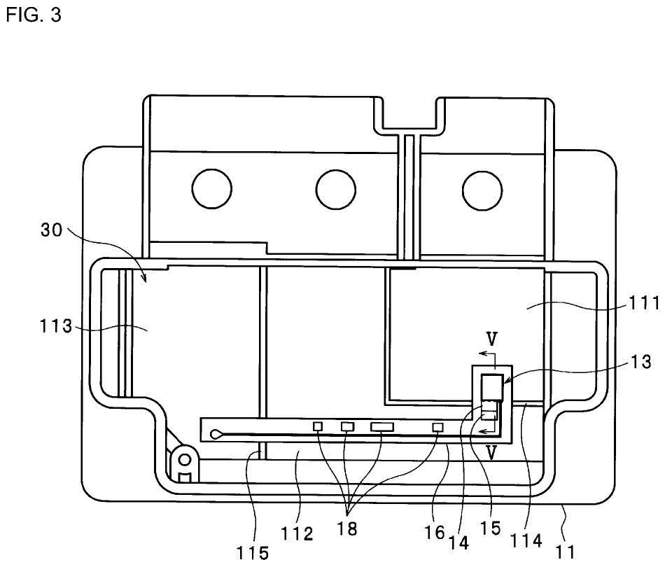

FIG. 3 is a plan view of the substrate structure 10 of the electrical apparatus 1 of the present embodiment, as seen from above. For convenience in the description, FIG. 3 shows the substrate structure 10 in a state where the control circuit 12 has been removed.

The substrate structure 10 includes the power circuit 30, the control circuit 12 for mounting a control circuit that applies on/off signals to the power circuit 30, and a housing portion 11 that houses the power circuit 30 and the control circuit 12. The control circuit 12 and the power circuit 30 are provided at locations separated from each other.

The power circuit 30 includes at least bus bars 111 and 112 (conductive pieces) and a semiconductor switching element 13 (semiconductor element) that receives a control signal from the control circuit 12 and switches between a conductive/non-conductive state based on the received control signal.

In the power circuit 30, the bus bars 111 and 112 are provided flush with each other, and a substrate portion 113 having a circuit pattern or the like is also provided flush with the bus bar 111 and 112. A first insulation region 114 is arranged between the bus bar 111 and the bus bar 112, and a second insulation region 115 is arranged between the bus bar 112 and the substrate portion 113.

The bus bar 111 is rectangular plate-shaped, and the bus bar 112 is provided so as to be near two adjacent sides of the bus bar 111. Similarly to the bus bar 111, the bus bar 112 is also plate-shaped. The bus bar 112 is arranged between the substrate portion 113 and the bus bar 111. The bus bar 111 and the bus bar 112 are conductive plate members formed by a metal material such as copper or a copper alloy.

The first insulation region 114 and the second insulation region 115 are manufactured by performing insert molding with use of an insulating resin material such as phenol resin or a glass epoxy resin. The first insulation region 114 and the second insulation region 115 may be formed integrally with the housing portion 11, for example.

The semiconductor switching element 13 is an FET (more specifically, a surface mount type power MOSFET) for example, and is arranged on the bus bar 111 or the bus bar 112. Specifically, in the power circuit 30 according to the present embodiment, the semiconductor switching element 13 (hereinafter referred to as the FET 13) is not arranged so as to straddle the bus bar 111 and the bus bar 112, but rather is fixed to either the bus bar 111 or the bus bar 112. In the present embodiment, for the sake of convenience in the description, the following describes the case where the FET 13 is fixed to the bus bar 111.

Also, in addition to the FET 13, semiconductor elements such as Zener diodes are mounted on the bus bars 111 and 112.

Note that although only one FET 13 is mounted in the configuration in the example shown in FIG. 3 for the sake of convenience in the description, there is no limitation to this, and it goes without saying that multiple FETs 13 may be mounted.

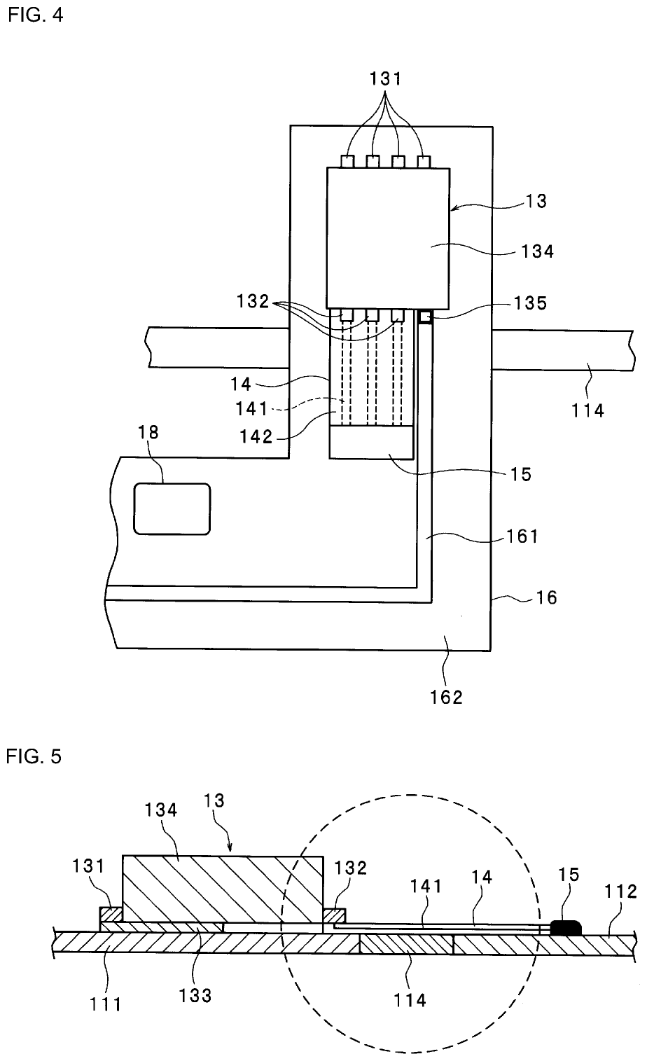

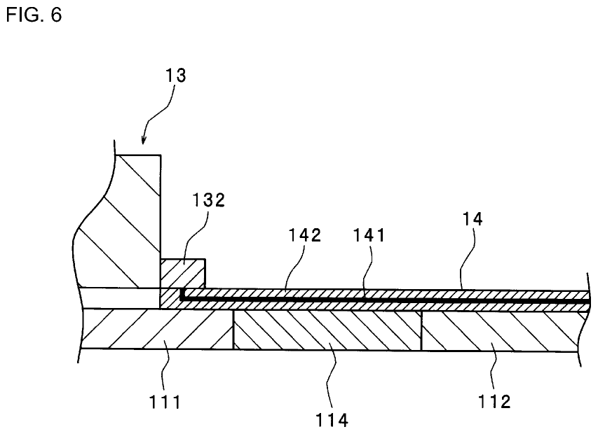

FIG. 4 is an enlarged view of a region that includes the FET 13 in FIG. 3, FIG. 5 is a longitudinal sectional view taken along a line V-V in FIG. 3, and FIG. 6 is an enlarged view of a portion indicated by a dashed-line circle in FIG. 5.

The FET 13 includes an element main body 134 as well as four drain terminals 131 and three source terminals 132 that are arranged on mutually opposite sides of the element main body 134. For example, the drain terminals 131 are provided on one lateral surface of the element main body 134, and the source terminals 132 are provided on the opposing lateral surface. The FET 13 also includes a gate terminal 135, and the gate terminal 135 is provided in the vicinity of the source terminals 132, for example. However, the position of the gate terminal 135 is not limited to this example.

In the present embodiment, the case where the FET 13 is fixed to the bus bar 111 and the source terminals 132 are electrically connected to the bus bar 112 via a connection sheet 14 is described as an example, but the present disclosure is not limited to this. A configuration is possible in which the FET 13 is fixed to the bus bar 112, and the drain terminals 131 are electrically connected to the bus bar 111 via the connection sheet 14.

The drain terminals 131, the source terminals 132, and the gate terminal 135 extend in a straight line outward from the element main body 134. The drain terminals 131, the source terminals 132, and the gate terminal 135 do not have a bent portion, thus suppressing the lengths to the extending ends, and achieving compactness for the power circuit 30.

The FET 13 is fixed to the bus bar 111 by soldering. Specifically, solder fixing portions 133 (fixing portions) are arranged between the bottom face of the FET 13 and the bus bar 111. The solder fixing portions 133 solder at least a portion of the bottom face of the FET 13 to the bus bar 111.

The drain terminals 131 of the FET 13 are soldered to the solder fixing portions 133, and are electrically connected to the bus bar 111 via the solder fixing portions 133. In other words, the drain terminals 131 are directly electrically connected to the bus bar 111.

On the other hand, the source terminals 132 of the FET 13 are electrically connected to the bus bar 112, which is on the other side of the first insulation region 114, via the connection sheet 14. In other words, the connection sheet 14 is provided on the bus bars 111 and 112 so as to extend across the first insulation region 114.

The connection sheet 14 includes linear conductive portions 141 (shown by dashed lines in FIG. 4), which electrically connect the source terminals 132 to the bus bar 112, and an insulation portion 142 that insulates the conductive portions 141 from the bus bar 111. Ends of the conductive portions 141 on one side are soldered to corresponding source terminals 132, and the ends of the conductive portions 141 on the other side are soldered to the bus bar 112. In other words, the other end of the connection sheet 14 is connected to the bus bar 112 via a solder connection portion 15.

As one example, the conductive portions 141 are made of copper foil, the insulation portion 142 is made of a resin sheet, and the conductive portions 141 are embedded in the insulation portion 142. The connection sheet 14 may be an FPC (Flexible Printed Circuit), for example.

The connection sheet 14 is partially fixed to any of the bus bars 111 and 112 and the first insulation region 114. For example, the connection sheet 14 is fixed at one to three locations in the length direction (the extending direction of the conductive portions 141) by an adhesive or the like applied linearly in a direction that intersects the length direction.

In other words, the connection sheet 14 is fixed to any of the bus bars 111 and 112 and the first insulation region 114 at only one or more locations, and can be loosened. Accordingly, the connection sheet 14 can deform to a certain extent in the length direction.

Also, the gate terminal 135 of the FET 13 is electrically connected to a distant substrate portion 113 by the bus bar 112 via an extended connection sheet 16. The extended connection sheet 16 is provided on the bus bars 111 and 112, and extends from the bus bar 111, over the bus bar 112, to the substrate portion 113.

The extended connection sheet 16 includes a conductive wire 161 that electrically connects the gate terminal 135 and the substrate portion 113, and an insulation sheet 162 that insulates the conductive wire 161 from the bus bars 111 and 112.

One end of the conductive wire 161 is soldered to the gate terminal 135, and the other end of the conductive wire 161 is soldered to a circuit pattern (not shown) of the substrate portion 113. The conductive wire 161 is made of a copper wire or copper foil, and the insulation sheet 162 is made of a resin. The insulation sheet 162 is adhered to the bus bars 111 and 112 along the conductive wire 161. The insulation sheet 162 covers a region including the conductive wire 161 and also a predetermined range of the bus bars 111 and 112 that includes the FET 13 region.

Circuit elements 18 (hereinafter also called upper circuit elements 18) such as resistors, coils, capacitors, and semiconductor elements are further mounted on the insulation sheet 162. The upper circuit elements 18 on the insulation sheet 162 are insulated from the bus bars 111 and 112 by the insulation sheet 162. The upper circuit elements 18 may be electrically connected to a circuit pattern (not shown) formed on the insulation sheet 162, or connected to the substrate portion 113 via predetermined conductive wires formed in the insulation sheet 162, for example. The extended connection sheet 16 may be an FPC (Flexible Printed Circuit), for example.

In this way, in the power circuit 30 according to the present embodiment, semiconductor elements can be arranged on the bus bars 111 and 112 as well without a complex configuration and without the addition of separate parts, thus making it possible achieve compactness for the power circuit 30.

As one example, the substrate portion 113 may be configured such that an insulated substrate is provided, a control circuit (not shown) that includes circuit elements such as resistors, coils, capacitors, and diodes is mounted on the upper surface of the insulated substrate, and a circuit pattern that electrically connects the circuit elements is also formed on the upper surface.

In the above description, an example is described in which the FET 13 is fixed to the bus bar 111, the drain terminals 131 of the FET 13 are directly connected to the bus bar 111, and the source terminals 132 of the FET 13 are connected to the bus bar 112 via the connection sheet 14. However, the embodiments are not limited to this configuration. A configuration is possible in which the FET 13 is fixed to the bus bar 112, the source terminals 132 of the FET 13 are directly connected to the bus bar 112, and the drain terminals 131 of the FET 13 are connected to the bus bar 111 via the connection sheet 14.

There are cases where a semiconductor element that has different terminals on opposite sides is mounted on bus bars separated via an insulation portion (or a gap), such as in the power circuit 30 of the present embodiment. In such a case, when the terminals of the semiconductor element are directly soldered to the corresponding bus bars, the distance between adjacent terminals needs to be larger than the width of the insulation portion, thus constraining the selection of the semiconductor element.

For example, even if the distance between adjacent terminals of the semiconductor element is larger than the width of the insulation portion, the semiconductor element needs to be arranged in the vicinity of the insulation portion, which is a constraint in terms of the circuit design, and which reduces the degree of freedom.

To address this, in the power circuit 30 of the present embodiment, the drain terminals 131 or the source terminals 132 are electrically connected to the bus bar 111 or the bus bar 112 using the connection sheet 14.

Accordingly, the distance between adjacent terminals does not need to be given consideration when selecting a semiconductor element, and the degree of freedom in selection can be increased.

Also, the position of the semiconductor element is not limited to being on the insulation portion or in the vicinity of the insulation portion, thus making it possible to increase the degree of freedom in circuit design.

Also, because the insulation portion is made of a different material from the bus bars, the insulation portion and the bus bar have different thermal expansion coefficients. Accordingly, when thermal expansion occurs, the insulation portion deforms. For example, if the semiconductor element is fixed to the insulation portion by soldering or the like, when the insulation portion deforms, stress becomes concentrated at the fixing portion of the semiconductor element, and the fixing portion becomes damaged.

In contrast, in the power circuit 30 of the present embodiment, the FET 13 is fixed to the bus bar 111 or the bus bar 112 instead of being fixed to the insulation portion, thus making it possible to prevent the concentration of stress caused by a difference in thermal expansion coefficient.

Furthermore, because the FET 13 is fixed to the bus bar 111 or the bus bar 112, heat generated in the semiconductor element (FET 13) during energization is transmitted to the bus bar 111 or the bus bar 112. Accordingly, it is possible to prevent a problem from occurring in the semiconductor element itself due to heat generated by the semiconductor element.

If heat is generated by the semiconductor element during energization, the heat is transmitted to the terminals as well. If the terminals undergo thermal expansion or contraction, stress becomes concentrated at the connection portion between the terminals and copper wires. If the terminals have a bent portion, then even in the case where the terminals undergo thermal expansion or contraction, the stress is mitigated by deformation of the bent portion.

However, if the terminals do not have a bent portion, such as in the FET 13, the length to the extending ends is short, it is not possible to expect the mitigation of stress by terminal deformation, and there is a risk of electrical disconnection occurring at the connection portions.

To address this, in the power circuit 30 of the present embodiment, the drain terminals 131 or the source terminals 132 are electrically connected to the bus bar 111 or the bus bar 112 using the connection sheet 14, and furthermore, the connection sheet 14 is fixed only partially.

Accordingly, the connection sheet 14 can deform to a certain extent in the length direction, and the connection sheet 14 deforms in accordance with thermal expansion or contraction of the drain terminals 131 or the source terminals 132, thus making it possible to prevent electrical disconnection at the connection portions of the terminals.

Although the case where the upper circuit elements 18 are provided on the insulation sheet 162 is described in the present embodiment, there is no limitation to this, and the upper circuit elements 18 may also be provided on the connection sheet 14 (insulation portion 142).

The embodiments disclosed here are to be considered in all respects as illustrative and not limiting. The scope of the present disclosure is indicated by the claims rather than by the foregoing description, and all changes which come within the meaning and range of equivalency of the claims are intended to be embraced therein.

1. A circuit board including a plurality of conductive pieces that are connected to a plurality of terminals of a semiconductor element, are provided flush with each other, and are each insulated from other conductive pieces, the circuit board comprising:
an insulation member arranged between the conductive pieces;
a first conductive piece connected to a first terminal of the semiconductor element;
a fixing portion of the semiconductor element that is arranged on the first conductive piece; and
a second conductive piece connected to a second terminal of the semiconductor element via a conductive connection sheet.

2. The circuit board according to claim 1,
wherein the connection sheet is provided on the first conductive piece or the second conductive piece and includes
a conductive portion that connects the second terminal and the second conductive piece, and
an insulation portion that insulates the first conductive piece from the conductive portion.

3. The circuit board according to claim 1, further comprising:
a conductive wire that connects a third terminal of the semiconductor element to a member other than the first conductive piece and the second conductive piece; and
an insulation sheet that insulates the conductive wire from the first conductive piece and the second conductive piece.

4. The circuit board according to claim 3,
wherein the insulation sheet is adhered to the first conductive piece or the second conductive piece, and
the circuit board further comprises an upper circuit element arranged on the insulation sheet.

5. The circuit board according to claim 1, wherein the connection sheet is an FPC (Flexible Printed Circuit).

6. The circuit board according to claim 5, wherein the connection sheet is partially fixed.

7. The circuit board according to claim 1, wherein the first terminal and the second terminal extend in a straight line from a main body of the semiconductor element.

8. The circuit board according to claim 2, further comprising:
a conductive wire that connects a third terminal of the semiconductor element to a member other than the first conductive piece and the second conductive piece; and
an insulation sheet that insulates the conductive wire from the first conductive piece and the second conductive piece.

9. The circuit board according to claim 2, wherein the connection sheet is an FPC (Flexible Printed Circuit).

10. The circuit board according to claim 3, wherein the connection sheet is an FPC (Flexible Printed Circuit).

11. The circuit board according to claim 4, wherein the connection sheet is an FPC (Flexible Printed Circuit).

12. The circuit board according to claim 2, wherein the first terminal and the second terminal extend in a straight line from a main body of the semiconductor element.

13. The circuit board according to claim 3, wherein the first terminal and the second terminal extend in a straight line from a main body of the semiconductor element.

14. The circuit board according to claim 4, wherein the first terminal and the second terminal extend in a straight line from a main body of the semiconductor element.

15. The circuit board according to claim 5, wherein the first terminal and the second terminal extend in a straight line from a main body of the semiconductor element.

16. The circuit board according to claim 6, wherein the first terminal and the second terminal extend in a straight line from a main body of the semiconductor element.
